(19) United States
(12) Patent Application Publication
(10) Pub. No.: US 2024/0387765 A1
(43) Pub. Date: Nov. 21, 2024

(54) AVALANCHE PHOTODIODE USING A SILICON CAP LAYER

(71) Applicant: Cisco Technology, Inc., San Jose, CA (US)

(72) Inventors: Gianlorenzo MASINI, Carlsbad, CA (US); Long CHEN, Marlboro, NJ (US)

(21) Appl. No.: 18/317,736

(22) Filed: May 15, 2023

(51) Int. Cl. H01L 31/107; H01L 31/028; H01L 31/105; H01L 31/18

(52) U.S. Cl. CPC H01L 31/107; H01L 31/028; H01L 31/105; H01L 31/1804

(57) ABSTRACT

Embodiments herein describe an APD architecture that includes a silicon cap layer formed on top of a germanium layer (e.g., a Ge absorption region). The silicon cap layer can form a multiplication region of the APD. Moreover, a charge layer can be formed between the absorption region and the silicon cap layer (e.g., the multiplication region).

### TECHNICAL FIELD

Embodiments presented in this disclosure generally relate to avalanche photodiodes (APD). More specifically, embodiments disclosed herein describe APDs that include a silicon cap layer on a germanium absorption region.

### BACKGROUND

Germanium on Silicon integrated waveguide APDs are composed of an absorption region (e.g., germanium (Ge)) and a multiplication region formed from doped silicon placed on a silicon on insulator (SOI) layer above a buried oxide (BOX). Because of this arrangement, photo carriers generated in the absorption region travel laterally throughout the width of the absorption region.

The multiplication region layer experiences a high field during operation as a result of the applied bias to the APD that splits between the Ge absorption region and the silicon multiplication region according to the device geometry and the extent and doping level of a charge layer. The high field region in the multiplication region performs photocarrier multiplication by means of the avalanche effect. Photogenerated electrons injected from the absorption layer are accelerated in the multiplication region and create a secondary photocurrent due to impact ionization events.

Accelerated carriers in the multiplication region (either primary photo carriers or secondary carriers) are likely to be scattered and injected in the oxide (e.g., the BOX) surrounding the silicon multiplication region, which is called hot carrier injection (HCl). HCl creates a fixed charge that, with time, causes a distortion of the electric field in the multiplication region and consequently a degradation of the ability of the APD to provide photocurrent gain. Put differently, the charge carriers accumulate over time in the oxide surrounding the APD which can create an electric field that alters the behavior of the APD.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates an APD with a silicon cap layer as a multiplication layer, according to one embodiment.

FIG. 2 illustrates an APD with a silicon cap layer as a multiplication layer, according to one embodiment.

FIG. 3 is a flowchart for forming an APD with a silicon cap layer, according to one embodiment.

FIGS. 4A-4G illustrate a process flow for fabricating an APD with a silicon cap layer, according to one embodiment.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure is an avalanche photodiode (APD) that includes a dielectric layer, a silicon layer disposed on the dielectric layer, a germanium absorption region disposed on the silicon layer, a silicon cap layer disposed on the germanium absorption region where the silicon cap layer comprises a multiplication region, and a cathode electrode coupled to the silicon cap layer.

Another embodiment presented in this disclosure is an APD that includes a buried oxide (BOX) layer, a silicon layer disposed on the BOX layer, a germanium layer disposed on the silicon layer, a silicon cap layer disposed on the germanium layer where the silicon cap layer comprises a multiplication region, and a cathode electrode coupled to the silicon cap layer.

Another embodiment presented in this disclosure is a method that includes forming a germanium absorption region on a silicon layer, forming a silicon cap layer on the germanium absorption region where the silicon cap layer comprises a multiplication region for the APD, and coupling a cathode electrode to the silicon cap layer.

### EXAMPLE EMBODIMENTS

Embodiments herein describe an APD architecture that includes a silicon cap layer formed on top of a germanium layer (e.g., a Ge absorption region). The silicon cap layer can form a multiplication region of the APD. Advantageously, the silicon cap layer may establish a multiplication region that is larger than a silicon multiplication region formed in a silicon substrate. The cap layer can have an electric field in the multiplication region shaped in such a way that the hot carriers can be driven away from the surrounding oxide thus reducing the risk of HCl degradation.

In one embodiment, a charge layer is formed between the silicon cap layer and the absorption region. The charge layer can be formed from the same material as the absorption region—e.g., Ge—but can be doped in order to form the charge layer (e.g., doped P-type). In one embodiment, because of the location of the charge layer on the absorption layer, the charge layer can be doped used in-situ doping. By using this doping technique (as opposed to ion implantation), the thickness and the doping level can be more tightly controlled. This can result in a charge layer that is better able to repartition an applied bias (voltage) between the absorption region and the multiplication region so that the absorption region has a low or weak electric field and the multiplication region has a high or strong electric field.

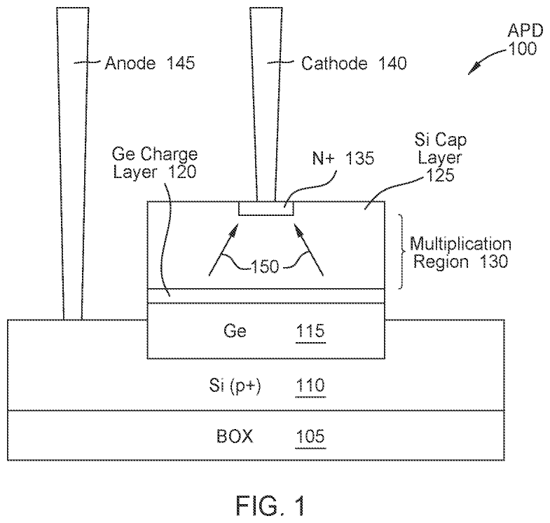

FIG. 1 illustrates an APD 100 with a silicon cap layer 125 as a multiplication region 130, according to one embodiment. The APD 100 includes a silicon (Si) layer 110 disposed on an oxide 105 which can be silicon dioxide or any other suitable insulator. In one embodiment, the oxide 105 and the silicon layer 110 are part of a SOI structure, where the oxide 105 is a BOX. However, the embodiments are not limited to such, and can be applied to any device that includes a crystalline silicon layer deposited on a dielectric layer.

In one embodiment, the silicon layer 110 is doped P-type (e.g., is a P-doped region). In one embodiment, the silicon layer 110 is heavily doped P-type (P+ or P++).

In this example, a germanium (Ge) absorption region 115 is recessed into the silicon layer 110. In one embodiment, the Ge absorption region 115 is undoped, or is lightly doped. In any case, the Ge absorption region 115 is lighter doped than the silicon layer 110.

As light strikes the germanium absorption region 115, it creates photo carriers in the region 115. The positive photo carriers (e.g., holes) move towards an anode electrode 145 through the P-doped silicon layer 110 while the negative photo carriers (e.g., electrons) move toward a cathode electrode 140.

The thickness of the germanium absorption region 115 can range from 100-500 nm. The width of the germanium absorption region 115 can range from 500-1000 nm.

In this example, a Ge charge layer 120 is disposed on the Ge absorption region 115. That is, in this embodiment, both the charge layer 120 and the Ge absorption region 115 are formed from Ge. As will be discussed in more detail below, the charge layer 120 can be formed as part of the process of forming the Ge absorption region 115 on the silicon layer 110. For example, Ge can be epitaxially grown on the silicon layer 110 to first form the Ge absorption region 115 and then Ge can continue to be grown to form the charge layer 120. In-situ doping (as opposed to ion implantation) can be used to dope the Ge charge layer 120 P-type (e.g., the charge layer 120 is P-doped), which can result in the charge layer 120 being much thinner (e.g., 10-50 nm) compared to charge layers doped using ion implantation.

A silicon cap layer 125 is in turn disposed on the Ge charge layer 120. The silicon cap layer 125 can form the multiplication region 130 of the APD 100. In conventional or previous APDs, the multiplication region is often located in the silicon layer 110, between the anode electrode 145 and the Ge absorption region 115. As a result, the charge layer is also located in the silicon layer 110, between the silicon multiplication region and the Ge absorption region 115. However, in FIG. 1, both the charge layer 120 and the silicon cap layer 125 (e.g., the multiplication region) are disposed on the Ge absorption region 115. This means the silicon cap layer 125 can be a much larger area than if the multiplication region was disposed in the silicon layer 110. For example, the silicon cap layer 125 can have a width of at least 500 nm (but can be much larger—e.g., 1000 nm or more) and a height of at least 100 nm (but can be larger—e.g., 200 nm or more). The greater width of the silicon cap layer 125 means it is better at preventing the photo carriers injected by the Ge absorption region 115 into the silicon cap layer 125 from escaping into the surrounding oxide. Moreover, the thickness of the layer 125 can be precisely controlled thus helping with uniformity of device characteristics (breakdown voltage).

The cathode region 135 (e.g., an N-doped region) may be formed by doping a top region or portion of the silicon cap layer 125. For example, ion implantation can be used to form the cathode region 135 (e.g., heavily doped N-type) of the silicon cap layer 125. In one embodiment, the remaining portion of the silicon cap layer 125 may be formed from intrinsic silicon (e.g., undoped silicon). Alternatively, the silicon cap layer 125 may be lightly doped, and in any case, is lighter doped than the cathode region 135.

In this embodiment, the silicon cap layer 125 is disposed in an area separated from the dielectric material (e.g., oxide) surrounding the APD 100. In doing so, the electric field in the multiplication region 130 is shaped in such a way that the hot carriers can be driven far from the surrounding oxide thus reducing the risk of HCl degradation. That is, by placing the cathode region 135 in the middle of the silicon cap layer 125, it reduces the chance that the hot carriers will escape into the surrounding oxide.

The arrows 150 in FIG. 1 outline the trajectory of the accelerated photoelectrons injected from the Ge absorption region 115 that generate the secondary photocurrent in the multiplication region 130. The arrows 150 indicate that the photoelectrons are unlikely to escape into the surrounding dielectric material, and instead stay within the silicon cap layer 125 until reaching the cathode region 135.

As discussed below, in one embodiment, the silicon cap layer 125 is grown epitaxially from the underlying Ge forming the charge layer 120 and the absorption region 115. However, this is not a requirement. Any silicon formation technique can be used to create the cap layer 125 so long as the silicon is high enough quality to serve as a multiplication region 130.

The cathode region 135 (e.g., N+ doped silicon) can be connected to the cathode electrode 140.

In addition to mitigating HCl, another advantage of the APD 100 relative to prior APD structures is that this architecture allows to precisely define the charge layer 120 (e.g., a P-type doped region in the Germanium abutting the multiplication region) by using in-situ doping. In-situ doping is much more controllable than implant doping, especially in the lateral direction. The functionality of the charge layer 120 is strongly dependent on its thickness (e.g., between 10 nm and 50 nm) and doping level since the charge layer 120 determines the repartition of the applied bias between the Ge absorption region 115 and the multiplication region 130 in the silicon cap layer 125 (high field). Put differently, the charge layer 120 ensures that most of the voltage drop between the cathode electrode 140 and the anode electrode 145 occurs with the silicon cap layer 125 (e.g., 90%) rather than in the Ge absorption region 115 or the silicon layer 110. As such, a well formed charge layer 120 ensures that the multiplication region 130 has a much stronger electric field than the electric field in the absorption region 115. Because the thickness and doping levels of the charge layer 120 can be more tightly controlled when located on the Ge absorption region (because of in-situ doping), the charge layer 120 may have improved characteristics relative to a charge layer formed in the silicon layer 110.

Although FIG. 1 illustrates the germanium absorption region 115 extending above a top surface of the silicon layer 110 this is not a requirement. In other embodiments, the top surface of the germanium absorption region 115 may be on the same plane as (or recessed below) the top surface of the silicon layer 110. In one embodiment, the top surface of the charge layer 120 may be on the same plane as (or recessed below) the top surface of the silicon layer 110.

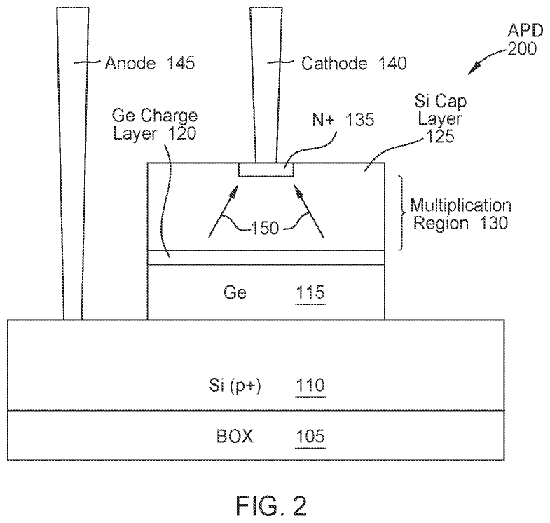

FIG. 2 illustrates an APD 200, according to one embodiment. While FIG. 1 illustrates at least a portion of the germanium absorption region 115 extending below a top surface of the silicon layer 110 (e.g., recessed below the top surface of the silicon layer 110), FIG. 2 illustrates the Ge absorption region 115 being formed on the top surface of the silicon layer 110. Both of the architectures illustrated in FIGS. 1 and 2 are possible, although recessing the absorption region 115 in the silicon layer 110 as shown in FIG. 1 may help with photo absorption.

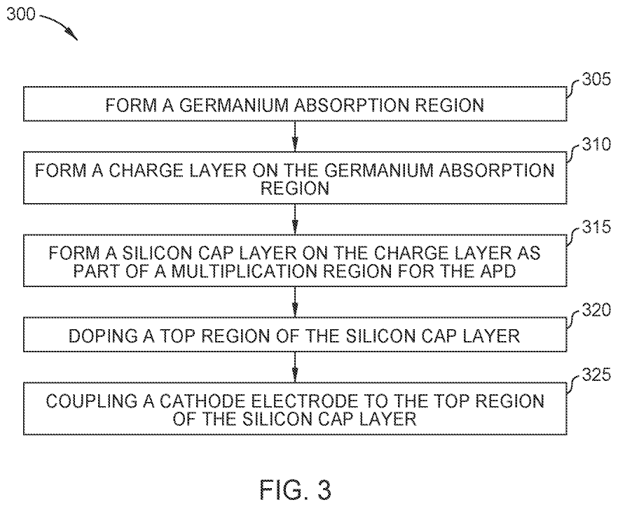

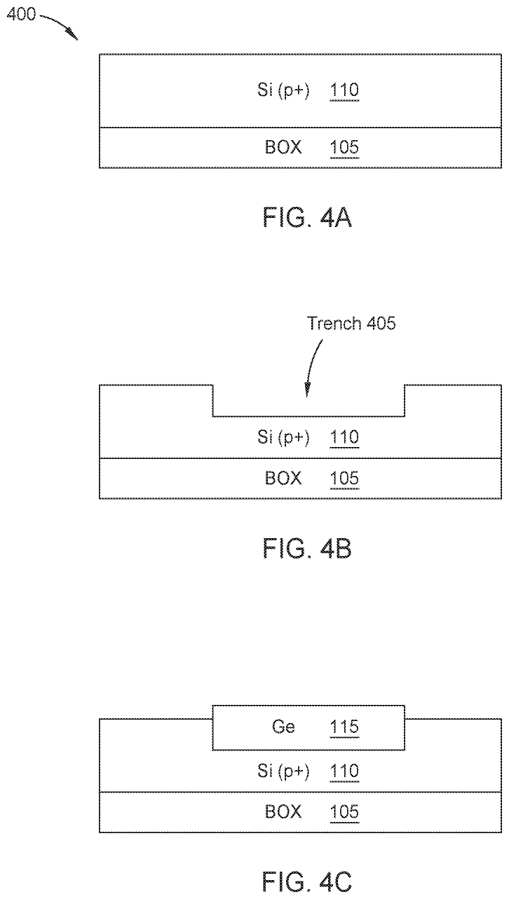

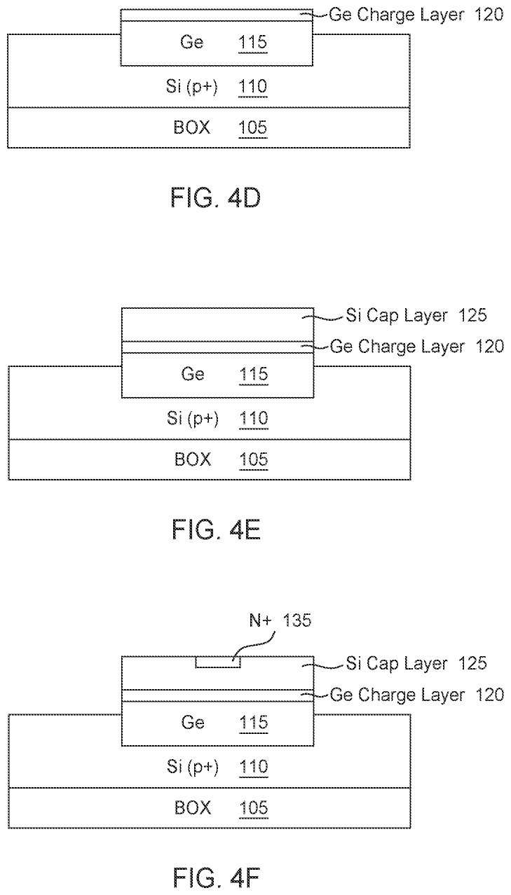

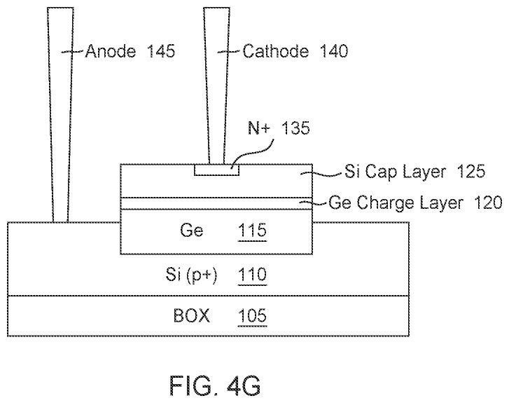

FIG. 3 is a flowchart of a method 300 for forming an APD with a silicon cap layer, according to one embodiment. For clarity, the method 300 is discussed in tandem with FIGS. 4A-4G which illustrate a process flow for fabricating an APD with a silicon cap layer, according to one embodiment.

For example, the method 300 may start with a structure illustrated in FIG. 4A which illustrates a wafer 400 that includes a silicon layer 110 formed on an oxide 105. The wafer 400 may be a SOI structure where the oxide 105 is a BOX. Thus, there may be a crystalline silicon substrate below the oxide 105 in the wafer 400, which is not shown.

At block 305, a Ge absorption region is formed on the silicon layer. In one embodiment, the Ge absorption region is recessed, at least partially, in the silicon layer. For example, FIG. 4B illustrates forming a trench 405 in the silicon layer 110. The trench 405 can be formed using any suitable lithographic technique. In this example, the trench 405 is formed from a etch that does not extend all the way through the silicon layer 110. That is, a portion of the silicon layer 110 separates the trench 405 from the oxide 105. In this example, the trench 405 is surrounded on all sides by the P+ doped silicon layer 110.

However, in another embodiment shown in FIG. 2, the Ge absorption region may not be recessed into the silicon layer 110. In that case, the method 300 may not include forming the trench 405 in FIG. 4B. Instead, the Ge absorption layer can be formed on the top surface of the silicon layer 110.

FIG. 4C illustrates forming the Ge absorption region 115 within the trench 405 shown in FIG. 4B. In one embodiment, the Ge forming the region 115 is epitaxially grown on the silicon layer 110. However, the embodiments herein are not limited to any particular technique for forming the Ge absorption region so long as the region is suitable for photo detection.

In one embodiment, the Ge absorption region 115 is undoped. That is, when growing the region, no dopants are introduced. In another embodiment, the Ge absorption region 115 may be lightly doped. In any case, the Ge absorption region 115 may be lighter doped than the charge layer, which is discussed below.

At block 310, a charge layer is formed on the germanium absorption region. This is illustrated in FIG. 4D where the charge layer 120 is formed on the absorption region 115. In one embodiment, both the charge layer 120 and the absorption region 115 are formed by growing Ge epitaxially on the silicon layer 110. For example, the fabrication process may be controlled such that Ge is grown to form the absorption region 115 with a desired thickness (e.g., 100-500 nm). This Ge may be undoped or lightly doped. After reaching the desired thickness of the Ge absorption region 115, the Ge can continue to be grown but this time in the presence of a dopant material to form the charge layer 120 (i.e., perform in-situ doping). As such, the charge layer 120 can directly contact the Ge absorption region 115.

Because the growth rate of the Ge and the presence of the dopant can be tightly controlled, this means the thickness and doping level of the charge layer 120 can also be tightly controlled. As discussed above, the charge layer 120 determines the repartition of the applied bias between the photogeneration region (i.e., the absorption region 115) in the Ge film (e.g., low electric field) and the multiplication region in the silicon cap (e.g., a high field) which is formed in the next block of the method 300. Being able to tightly control the thickness and doping level of the charge layer 120 improves its ability to ensure that most of the voltage drop (and the strongest electric field) is in the silicon cap layer.

At block 315, the silicon cap layer is formed on the charge layer, where at least a portion of the silicon cap layer forms a multiplication region for the APD. As shown in FIG. 4E, the silicon cap layer 125 is formed on the charge layer 120. In one embodiment, the silicon forming the cap layer 125 is epitaxially grown on the charge layer 120. Growing crystalline silicon for the cap layer 125 epitaxially ensures it will have a suitable quality to be used as a multiplication region (e.g., a low number of crystalline defects). However, the embodiments herein are not limited to epitaxially grown silicon, but rather any silicon formation can be used so long as the process yields crystalline or poly-crystalline silicon suitable as a multiplication region in an APD.

In one embodiment, the silicon in the cap layer 125 is undoped (or is lightly doped). In one embodiment, a width of the silicon cap layer 125 is at least 500 nm and a height of the silicon cap layer 125 is at least 100 nm.

At block 320, a top region of the silicon cap layer is doped to form a cathode region 135. As shown in FIG. 4F, a top region of the silicon cap layer is heavily doped N-type (e.g., N+) to form the cathode region 135. The dopants can be introduced into the silicon using ion implantation or any other suitable means.

In one embodiment, the location of the cathode region 135 in the silicon cap layer 125 is selected to reduce the likelihood that hot carriers will escape the silicon cap layer 125 into the surrounding oxide (which will surround the sides of top of the silicon cap layer 125 when the APD is finished being fabricated). For example, by centering the cathode region 135 (rather than placing the cathode region 135 near the sides of the cap layer 125) can help reduce the likelihood that hot carriers will escape into the oxide.

At block 325, a cathode electrode is coupled to the top region of the silicon cap layer. This is illustrated in FIG. 4G where the cathode electrode 140 contacts the cathode region 135 of the silicon cap layer 120.

In parallel processing steps (or using different processing steps), the anode electrode 145 can be formed to contact the silicon layer 110. In one embodiment, before forming the cathode electrode 140 and the anode electrode 145, oxide may be deposited on top of the structure shown in FIG. 4F. Holes can then be patterned and etched in the oxide in the desired locations of the electrodes 140 and 145. A conductive material (e.g., metal) can then be deposited in the holes to form the electrodes 140 and 145.

In this manner, an APD can be formed that includes a silicon cap layer 125 that serves as a multiplication region for the APD on top of a Ge absorption region 115. For the reasons above, this APD architecture can reduce HCl and improve the function of the charge layer, among other potential advantages.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

In view of the foregoing, the scope of the present disclosure is determined by the claims that follow.

We claim:

1. An avalanche photodiode (APD), comprising:
a dielectric layer;
a silicon layer disposed on the dielectric layer;
a germanium absorption region disposed on the silicon layer;
a silicon cap layer disposed on the germanium absorption region, wherein the silicon cap layer comprises a multiplication region; and
a cathode electrode coupled to the silicon cap layer.

2. The APD of claim 1, further comprising:
a N-doped region of the silicon cap layer, wherein the cathode electrode is connected to the N-doped region.

3. The APD of claim 2, wherein a remaining portion of the silicon cap layer is intrinsic silicon or is lighter doped than the N-doped region of the silicon cap layer.

4. The APD of claim 1, wherein the silicon layer is P-doped, further comprising:
an anode electrode connected to the silicon layer.

5. The APD of claim 1, wherein a portion of the germanium absorption region contacting the silicon cap layer forms a charge layer, wherein the charge layer is P-doped.

6. The APD of claim 5, wherein a remaining portion of the germanium absorption region is undoped germanium or is lighter doped than the charge layer.

7. The APD of claim 1, wherein a width of the silicon cap layer is at least 500 nm.

8. The APD of claim 7, wherein a thickness of the silicon cap layer is at least 100 nm.

9. An avalanche photodiode (APD), comprising:
a buried oxide (BOX) layer;
a silicon layer disposed on the BOX layer;
a germanium layer disposed on the silicon layer;
a silicon cap layer disposed on the germanium layer, wherein the silicon cap layer comprises a multiplication region; and
a cathode electrode coupled to the silicon cap layer.

10. The APD of claim 9, further comprising:
a N-doped region of the silicon cap layer, wherein the cathode electrode is connected to the N-doped region.

11. The APD of claim 10, wherein a remaining portion of the silicon cap layer is intrinsic silicon or is lighter doped than the N-doped region of the silicon cap layer.

12. The APD of claim 9, wherein the silicon layer is P-doped, further comprising:
an anode electrode connected to the silicon layer.

13. The APD of claim 9, wherein a portion of the germanium layer contacting the silicon cap layer forms a charge layer, wherein the charge layer is P-doped, wherein a remaining portion of the germanium layer is undoped germanium or is lighter doped than the charge layer.

14. The APD of claim 9, wherein a width of the silicon cap layer is at least 500 nm.

15. The APD of claim 14, wherein a thickness of the silicon cap layer is at least 100 nm.

16. A method of forming an APD, the method comprising:
forming a germanium absorption region on a silicon layer;
forming a silicon cap layer on the germanium absorption region, wherein the silicon cap layer comprises a multiplication region for the APD; and
coupling a cathode electrode to the silicon cap layer.

17. The method of claim 16, further comprising, before coupling the cathode electrode to the silicon cap layer:
doping a region of the silicon cap layer N-type, wherein the cathode electrode is connected to the region of the silicon cap layer.

18. The method of claim 17, wherein a remaining portion of the silicon cap layer is intrinsic silicon or is lighter doped than the region of the silicon cap layer.

19. The method of claim 16, further comprising, before forming the silicon cap layer:
forming a charge layer on the germanium absorption region, wherein the charge layer comprises germanium doped using in-situ doping, wherein the germanium absorption region is undoped germanium or is lighter doped than the charge layer.

20. The method of claim 19, wherein a thickness of the charge layer is less than 50 nm.
